(19) United States
(12) Patent Application Publication
(10) Pub. No.: US 2026/0147404 A1
(43) Pub. Date: May 28, 2026

(54) Method for non-intrusively analyzing human activity in a connected environment

(71) Applicant: ORANGE, Issy-les-Moulineaux (FR)

(72) Inventors: Anthony FOULONNEAU, CHATILLON CEDEX (FR); Jérémy LACOCHE, CHATILLON CEDEX (FR)

(21) Appl. No.: 19/363,738

(22) Filed: Oct. 21, 2025

(30) Foreign Application Priority Data
Nov. 25, 2024 (FR) FR2412960

(51) Int. Cl. G06F 3/01; G01D 21/02; G06F 30/20

(52) U.S. Cl. CPC G06F 3/011; G01D 21/02; G06F 30/20

(57) ABSTRACT

A method for determining a human activity in a real environment including at least one usage sensor for at least one device of the environment. The method includes learning by an artificial intelligence and an inference by the artificial intelligence to determine the human activity in the environment. For the learning by the artificial intelligence, the method includes generating artificial intelligence training data, based on a simulation of an activity of at least one autonomous agent operating within a simulation of the environment generated from a digital twin of the real environment and using at least one digital replica of the device.

### CROSS REFERENCE TO RELATED APPLICATION

This Application claims priority to and the benefit of French Patent Application No. FR2412960, filed Nov. 25, 2024, the content of which is incorporated herein by reference in its entirety.

### TECHNICAL FIELD

This disclosure relates to the field of sensor measurement analysis, and more particularly to the field of analyzing human activity in an environment equipped with sensors.

### PRIOR ART

The Internet of Things (IoT) allows devices in buildings, homes, and other premises to be interconnected for the purpose of exchanging data measured in their environment. In these connected environments, there may be dozens or even hundreds of sensors deployed to record a variety of data, particularly for user safety and environmental monitoring applications. These applications raise user privacy issues, as they generally involve the potentially intrusive collection and analysis of personal data, sometimes without the users'knowledge.

To circumvent these problems, methods have been developed that prioritize the analysis of data recorded by so-called “non-intrusive” sensors, i.e. sensors which, by themselves, do not allow identifying an individual or user or recording their personal information. Examples of these include sensors for acquiring physical environmental measurements (pressure, temperature, humidity), sensors for device activation (electrical outlets, switching on a lamp), etc., which do not allow this information to be linked to a specific user. However, these non-intrusive measurements do not in themselves constitute data allowing analysis of a type of human activity and cannot be used directly to assist in monitoring and user safety.

Work in artificial intelligence (AI) has thus sought to exploit this data provided by non-intrusive sensors, to produce information that is relevant to deducing user activity in connected environments. Traditionally, these methods require providing a learning phase for AI algorithms, generally in a supervised manner, which are based on training data produced by the sensors during the activity of operators performing actions in the connected environment.

This learning phase is nevertheless highly dependent on the connected environment and on the sensors it is equipped with. An algorithm trained in a given environment will thus prove ineffective in another environment having other types of sensors arranged differently, or in the case where the environment itself has a unique topology. Moreover, it is very long and costly to create this training data, and may require several days of recording data, with one or more operators living in the connected environment and annotating all their activities in order to train the AI.

Another approach allows eliminating the enlistment of human operators to work in the target environment for several days, by proposing a simulation of human activity in a copy of the environment, where the environment geometry and the arrangement of the sensors are modeled in 3D. The behavior of the sensors is also simulated. A virtual agent, or “autonomous agent,” which behaves as a human would in the real environment, is then implemented and “lives” in the copy of the environment for several weeks. The simulation of activity by the autonomous agent takes place at an accelerated pace, which reduces the time taken to produce training data.

However, this method remains partially automated and requires numerous, sometimes tedious, human interventions. In this method, operators must produce training data from the activity simulation, then implement it to train the algorithm, and then monitor its proper execution. Furthermore, the creation of the 3D environment requires precise mapping, which is carried out manually before the simulation begins.

### SUMMARY

The present disclosure improves the situation.

A method is proposed for determining a human activity in an environment comprising at least one usage sensor for at least one device of the environment, the method comprising a learning by an artificial intelligence and an inference by the artificial intelligence in order to determine the human activity in said environment. The method comprises, for the learning by the artificial intelligence:
generating artificial intelligence training data, based on a simulation of an activity of at least one autonomous agent operating within a simulation of the environment generated from a digital twin of the real environment and using at least one digital replica of said device.

Such an implementation thus allows fully automating the process of creating a replica of the real environment as well as that of generating training data. No human intervention is required, as data is generated and automatically annotated based on the interactions of the autonomous virtual agent with the replicas of the environment and of the devices, in the same manner that a human user would interact in a real environment and with devices of the environment.

The autonomous virtual agent is thus simulated in a manner that interacts freely, or at least partially freely, with the environment replica, without requiring human intervention. Such an autonomous agent thus eliminates the need for a prior recording of human activities being performed by operators.

“Inference by the artificial intelligence” is understood to mean the output produced by artificial intelligence in response to an activity in the real environment. This output may be, for example, the identification of a human behavior.

In one embodiment, the inference by the artificial intelligence may be carried out based on data captured during the use of said at least one device by at least one physical user, while having knowledge of the training data acquired from simulated uses of the digital replica of the device by said at least one autonomous agent.

Thus, in this embodiment, the artificial intelligence, which has been trained based on the simulation of the activity of the autonomous agent operating within the replica of the real environment, is implemented in the real environment with the real physical user, and advantageously produces accurate inferences and correctly identifies the human behavior and the human activity.

In one embodiment, the at least one autonomous agent used for generating the training data is chosen based on a profile of the at least one physical user.

In this example, the autonomous agent is thus configured to imitate the behavior of the user in their real environment. By more faithfully reproducing the user's behavior, the autonomous agent generates more relevant training data for the artificial intelligence, which further improves the accuracy of its inferences.

In one embodiment, the digital twin of the real environment is initialized prior to generating training data for the artificial intelligence, said digital twin being configured to reproduce a state and a behavior of the real environment by simulating the environment of said real environment, comprising the digital replica of said at least one device in the real environment.

According to one embodiment, the digital twin is generated from data of the real environment, including at least:
a type of business premises or residential premises,
a surface area of said premises,
functional spaces in said surface area, and types of functions of said spaces,
a state of said premises.

The digital twin is therefore created based on a set of information and data so as to be as faithful as possible to the real environment, its devices and their behavior.

According to another aspect, said at least one device in the real environment comprises at least:
a sensor for detecting the opening and/or closing of a water inlet;
a sensor for a connected power outlet;
a presence sensor;
a pressure sensor;
a sensor for detecting the turning on and/or off of a light;
a motion sensor for a door, blind, shutter, and/or window;
a thermostatic sensor;
a usage sensor for a household appliance; and/or
a usage sensor for a connected terminal.

Furthermore, according to one embodiment, said at least one sensor is connected to a local area network linked to a gateway connected to a server via a wide area network.

Such an implementation exploits some or all of the measurements and information captured by the non-intrusive sensors that may equip the real environment, these being non-intrusive, impersonal, indirectly linked to human activity, and by themselves not sufficient to identify a user.

According to one embodiment, the method of this disclosure may further comprise a step of monitoring an efficiency of the artificial intelligence, wherein the inference by the artificial intelligence is implemented on the basis of data captured during the simulation of the activity of the at least one autonomous agent operating within the simulation of the environment generated from the digital twin of the real environment, while having knowledge of the training data acquired from simulated uses of the digital replica of the device by the at least one autonomous agent, wherein a comparison of the inference produced by the artificial intelligence and the simulation of the activity of the at least one autonomous agent is evaluated, and if the comparison is greater than a predefined threshold, said training data is corrected relative to said data captured during the simulation of the activity of the at least one autonomous agent.

Furthermore, according to one possible embodiment, at least one new autonomous agent may be generated, depending on said comparison exceeding the predefined threshold, in order to generate new training data for the artificial intelligence.

This embodiment, in which an efficiency control step is implemented, allows further improving the responses produced by the artificial intelligence, which for example may be re-trained several times with the same autonomous agent operating within the same 3D simulation of the same digital twin, generating another iteration of training data, or may be re-trained in a completely new context, with another (or several) autonomous agent (parameterized differently), another 3D simulation, and/or another digital twin (with other devices for example), generating another set of training data, until convergence to a satisfactory efficiency (i.e. above the predefined threshold).

In one embodiment, the method may comprise an increase in a speed of operating of the at least one autonomous agent within said simulation of the environment generated from the digital twin, compared to an actual operating by at least one physical user within the real environment, in order to accelerate the simulation of activity by the at least one autonomous agent and of the generation of training data.

The autonomous agent, the 3D simulation of the digital twin, and the simulation of the agent's activity may be calculated by one or more processors. Such an implementation of the method, then fully automated, drastically increases the speed of training the artificial intelligence compared to semi-automatic training where human operators would perform actions and annotate all their activities for several days in a real environment.

According to one embodiment, each autonomous agent may operate within said simulation of the environment according to a decision made by the autonomous agent, based on a model of needs of the autonomous agent.

The autonomous agent may thus decide whether or not to perform certain activities, in order to have a more realistic and automated behavior that is similar to the behavior of a particular actual user.

According to another aspect, a computer program is also provided comprising instructions for implementing the method described in this disclosure, when executed by a processing circuit.

This disclosure also relates to a device able to comprise a processing circuit for implementing the method described.

Such a device may be integrated into the real environment, for example via a gateway of a local area network of the environment (for a solution of local activity analysis), or may be integrated into a remote server of a wide area network (for remote analysis by artificial intelligence).

### BRIEF DESCRIPTION OF DRAWINGS

Other features, details and advantages will become apparent from reading the detailed description below, and from analyzing the attached drawings, in which:

FIG. 1 illustrates an example of a real environment comprising interconnected devices and sensors, and a physical user operating within the real environment.

FIG. 2 shows an example of steps of the method of this disclosure as defined above, for analyzing the activity of a user and identifying their behavior in a real environment.

FIGS. 3A and 3B show two examples of a comparison between a real activity of a physical user in a real environment (black and white photographs on the left) and a simulated activity of an autonomous agent in a reproduction of the real environment (simulations on the right).

FIG. 4 illustrates an example of a simulation of the activity of an autonomous agent based on a needs model, according to one embodiment.

FIG. 5 shows an example of a 3D simulation based on a digital twin of the real environment of FIG. 1, in which an autonomous agent is performing actions, and implemented according to the above method.

FIG. 6 illustrates another example of a reproduction by a 3D simulation based on a digital twin of another real environment comprising several rooms, in which several autonomous agents are performing actions, and implemented according to the above method.

FIG. 7 shows an example of a processing circuit for implementing the method defined above, according to one embodiment.

### DETAILED DESCRIPTION OF CERTAIN ILLUSTRATIVE EMBODIMENTS

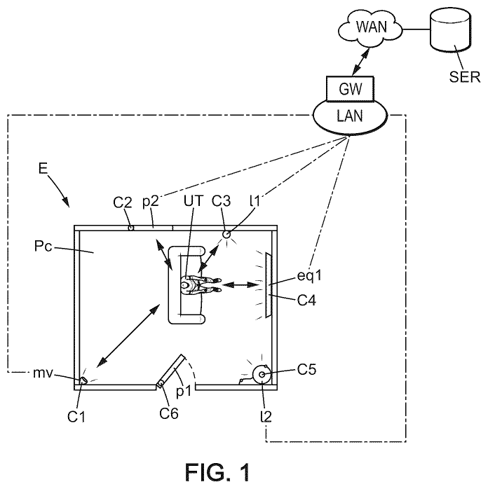

FIG. 1 shows an example of a real environment E which is of the connected home type, composed of a room Pc which includes various lifestyle devices. A physical user UT performs actions in this environment and interacts with the devices. In the illustrated example, the room Pc thus comprises a television eq, a wall light l1, a floor lamp l2, a door p, a window equipped with a blind p, and a motion detector mv, and each of these is equipped with at least one sensor C1 to C6 which are non-intrusive sensors. The devices can be interconnected via a gateway GW of a local area network LAN of the home. The information collected by the gateway can then be sent to a server SER via a wide area network WAN.

In this example, the user UT is watching multimedia content on the television eq, the lamps l1 and l2 in the room are on, the window blind is closed, the door p to the room is open, and the motion sensor mv detects the presence of the user in the room. The sensors C1 to C6 record measurements and information related to these devices. They may be activated together or separately, depending on the actions of the user UT. For example, the sensor C4 on the television eq indicates that the television is on and in operation, and the sensor C2 on the window is not in operation but has recorded an activation to lower the blind at a given time.

The real environment may include other types of sensors which may record other data for the same devices (e.g. a television sensor could also record the television's power consumption, a window sensor could measure an indoor/outdoor brightness ratio), and/or other sensors for other devices (not shown) which for example would be connected to electrical outlets, or for measuring physical data of the environment E, such as pressure, temperature, room humidity, the time, etc.

The following non-exhaustive list presents other examples of non-intrusive sensors which could be installed in the real environment: a sensor for detecting the opening or closing of a water inlet, a water flow measurement sensor, a usage sensor for a connected power outlet, a presence or motion sensor, a pressure sensor, a sensor for detecting the turning on or off of a light, a motion sensor for a door, blind, shutter, and/or window, a thermostatic sensor, a usage sensor for a household/electronic appliance, a usage sensor for a connected terminal, a router sensor with internet speed measurement, a humidity sensor, a brightness sensor, a smoke sensor, a sound activated sensor, etc.

These could also be presence sensors using “Wi-Fi sensing”, where an attenuation of a Wi-Fi signal emitted to a device is recorded, which can indicate the presence of a user between the device and a Wi-Fi transmitter.

However, the data collected by these non-intrusive sensors are not sufficient, on their own, for accurately analyzing or deducing human activity, particularly with regard to user safety in a real environment.

The proposed solution therefore implements a method for exploiting and taking advantage of all the information captured by such non-intrusive sensors in order to deduce the human activity, while avoiding the use of “intrusive” surveillance devices, i.e. with person recognition, such as cameras or microphones, which are generally used for activity analysis. It relies on the use of an AI algorithm, trained on a faithful digital reproduction of the environment and of the user's behavior.

Thus, this method, in addition to advantageously relying solely on non-intrusive data, is fully automated and requires little or no user intervention during the process.

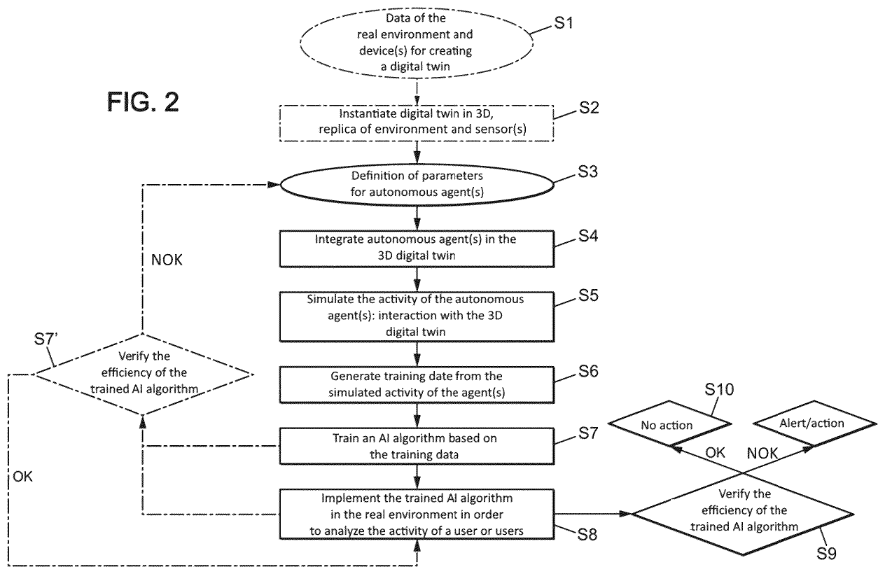

The steps of this method, according to a preferred embodiment, are presented in FIG. 2 and detailed in the following paragraphs.

In a first optional step S1, prior to the method, all the information and data are received concerning the real environment E, the placement, the behavior of the devices and their sensors.

To capture knowledge about the real environment E, several tools and measurements may be used such as augmented reality, geometric sensors, plans, construction files (building information modeling, BIM), etc. These data may be, for example, provided by the user or the owner, identified in databases and/or by an operator who enters the real environment in order to capture certain information directly.

This information may include, for example:
the type of premises, whether business premises or a residential dwelling,
the surface area of the premises, its numerical value and its shape,
the functional spaces within said surface area, for example: if it is a residential dwelling, it typically includes a bedroom, a kitchen, and/or an office,
the types of functions of the spaces, e.g. sleeping, entertaining, cooking, and/or working, etc.,
the known information about the devices and sensors present in the environment E, in particular, their location, the types of devices (household appliances, home automation, etc.) and sensors (physical measurement sensors, activation sensors, etc.), their function (heating, light, etc.) and their behavior (activated when a device is switched on/off, activated only during a defined time period and/or in response to a change, etc.),
the data measured by the sensors and how they are processed (recorded intermittently, sent to a local or remote entity, to a user, etc.).

In addition, data from the “nominal” or current state of the real environment E may be used as a reference, such as the temperature, pressure, and humidity values, as a function of the period, and any problems identified by a user/owner of the real environment (for example insufficient insulation, leaky pipes).

During a second optional step S2 prior to the method, all the information obtained in step S1 is then used to initialize the digital twin J of the real environment E. The digital twin is then not only a geometric reproduction of the environment; it also includes all the data on the physical state, behavior, furnishings, and/or devices, as well as how these devices are used.

Alternatively, the digital twin J may be received directly, without implementing steps S1 and S2. For example, the digital twin J may contain data structured in graph form (e.g. XML, JSON formats) as well as 3D model information associated with its elements (such as furniture) and data for modeling the behavior of the devices and sensors. Some or all of the data, and/or of the digital twin, may be transmitted by suppliers (providers of electricity, internet, water, etc.) who would also rely on a digital twin of the real environment, for example for their own consumption monitoring.

A 3D simulation is then instantiated from the digital twin J (for example using a 3D engine, such as Unity 3D or the Unreal Engine), representing a digital replica of the environment and of these devices, in which a 3D virtual agent (or autonomous agent) can operate and interact.

An example of the 3D reproduction from a digital twin J of the real environment E of FIG. 1 is presented in FIG. 5, where the room Pc1, all the devices eq1, l1, l2, p1, p2, mv, and their sensors C1 . . . C6 are reproduced, with the device replicas Req1, Rl1, Rl2, Rp1, Rp2 and the sensor replicas RC1 . . . RC6, in the room replica RPc1.

Once the digital twin J has been established and its 3D reproduction instantiated, a step S3 is implemented. In this step, user parameters are chosen and are used to generate one or more autonomous agents A1, A2, which must then operate in the digital twin J instantiated in 3D. The autonomous agent(s) are defined so as to reproduce the behavior of humans operating within the real environment and interacting with the devices automatically. In addition, the autonomous agent(s) can operate freely or at least partially freely, in order to reproduce a general behavior of a given user.

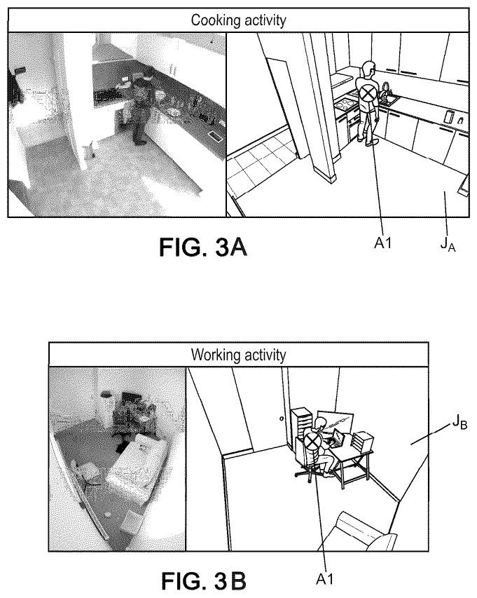

Two examples are illustrated in FIGS. 3A and 3B and show an autonomous agent A1 in a 3D simulation based on a digital twin J_{A}, J_{B}, reproducing the activity of a user in a real environment: in a kitchen preparing food (FIG. 3A) and in an office while working (FIG. 3B).

To obtain the most faithful reproduction possible of the behavior, the autonomous agent A1 is preferably configured according to a user profile of the user(s) of the real environment. Such a user profile may then include a set of information specific to the users, established beforehand.

For example, and without being limited to the following list, the user profile may comprise the age, gender, skills/aptitudes, job or type of work, moods, interests, preferred hours and types of activity, or any other relevant, non-intrusive information about the user(s).

Regardless of the parameters used to establish the user profile in order to initialize the autonomous agent, the aim of this disclosure is to be able to quickly identify a behavior of a physical user UT.

This identification of the behavior of the user UT can then be analyzed to determine whether the safety or status of the physical user is deteriorating in comparison to a behavior considered to be usual and/or a situation considered to be safe.

Additionally or alternatively, it is also possible to analyze or detect the user's current activity, assess their availability, predict their future activities, and/or automatically locate the room in which the user is located. These measurements may, for example, be used to adapt the services of the real environment, such as adjusting room temperatures, turning off the gas supply in the absence of the user, activating an intrusion alarm, allowing phone calls with an audible ring tone when the user is identified as available, etc.

A user behavior that does not endanger user safety is, for example, eating, sleeping, working, etc. It may also be adapted to a specific user, such as “the user sleeps three hours a night” or “sometimes works on Sundays.” Conversely, a behavior that could endanger user safety would be, for example, “falling down,” “not eating,” “leaving a gas supply open,” etc. The nature of the situation, safe or dangerous, may depend on both the user behavior and the state of the environment (for example, abnormal temperature, water leak), or may be indicated by default (“fire” situation). Any relevant provision for improving the identification of the behavior and the situation is to be considered.

Each type of behavior and situation may be implemented beforehand, during the instantiation of the 3D simulation, or during parameterization of the autonomous agent A1. Additionally or alternatively, usual/unusual behaviors and safe/dangerous situations may be learned by the AI algorithm after several days or weeks of implementing the method in the real environment, as described below in steps S8 to S10 of the method.

In addition, if relevant to ensuring the safety of a user and with the user's consent, in addition to the parameter examples described above, it may be envisaged to configure the user profile based on more intrusive data, such as medical data, in order to improve rapid response in the event of dangerous behavior or a risky situation. For example, a user suffering from epilepsy who is experiencing the behavior typical of an epileptic seizure (e.g. the user is lying on the floor but not on the bed or sofa and not during sleep or nap periods, indicating a potential seizure or loss of consciousness), could provide medical data and/or the nature of dangerous behaviors. In such a case, providing personal identification information would not be required.

Furthermore, in the case where several autonomous agents are defined, other interaction parameters may be considered, such as a family relationship, preferential interactions, etc. For example, in the case of autonomous agents reproducing two parent users with a child, the parent autonomous agents may thus be configured to monitor and/or take care of the child autonomous agent during defined periods, or to go to bed in separate rooms and at different times.

According to a preferred embodiment, and in order to reproduce the behavior of a user as faithfully as possible, the autonomous agent may also be initialized with a “needs model”, defined to reproduce the needs of a human user, and in particular the needs of the physical user UT.

Such a needs model may then comprise, according to one embodiment, a plurality of needs gauges, each individually increasing progressively over time and/or according to the activities of the autonomous agent and/or according to the user profile. These needs gauges are configured to create an urgency for accomplishing certain activities, called “needs”, by the autonomous agent A1 in the 3D simulation of the digital twin J.

A “decision” may be made by the autonomous agent, based on its needs model, to perform actions in the replica environment. The decision made by the autonomous agent imposes its activity on it. For example, if a needs gauge is high, the autonomous agent may decide to proceed with this need, or continue its current activity, or interact in a certain way with its environment. In this manner, the simulation of the autonomous agent is refined and allows for more realistic behavior; moreover, the simulation is thus fully automated.

Such a decision by the autonomous agent may be parameterized, for example according to a priority, or in a probabilistic/random and/or deterministic manner. For example, in the case of a priority, it may be decided that the needs gauge (for example “hunger”) cannot prevent the autonomous agent from completing a particular activity (for example “sleep”) during a predefined or equivalent time. Similarly, in the random case, the decision may be made to proceed as needed according to a predefined probability, and in the deterministic case, the decision may be made to proceed as needed according to predefined conditions (for example, the autonomous agent decides to eat as soon as the gauge requires it and if the agent is at home).

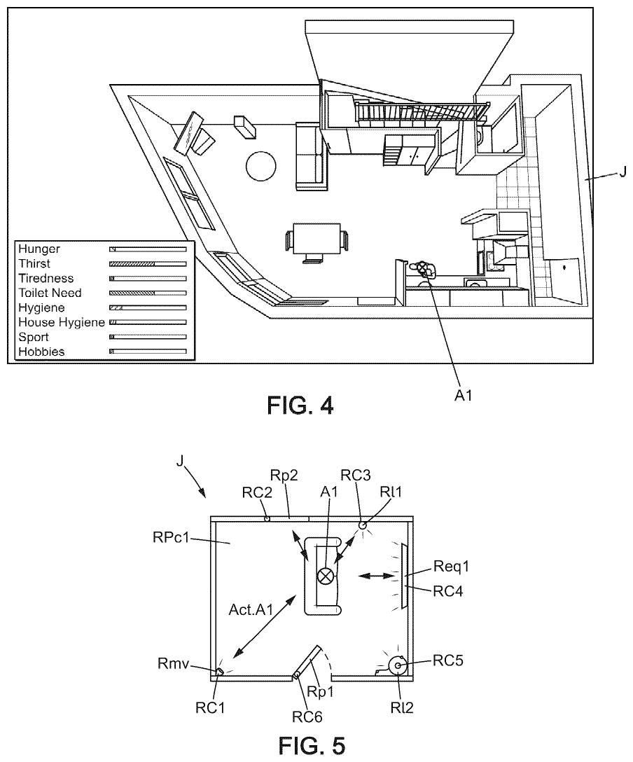

FIG. 4 shows an example visualization of the activity of the autonomous agent according to its needs model. In this illustrated and non-exhaustive example, the needs model may include a “thirst” gauge, which increases linearly over time and/or increases more during a sports activity or when eating, for example. When the thirst gauge increases beyond a predefined critical threshold (in FIG. 4, this is set at 60% of the gauge), the autonomous agent A1 is configured to pour itself a drink. When the autonomous agent has drunk, the thirst gauge decreases, and the agent can resume its other activities and continue to interact with the other devices of the digital twin J.

Furthermore, according to one embodiment, the autonomous agent A1 may also be configured according to a pre-established activity schedule (not shown). The activity schedule may control the actions and types of activities of the autonomous agent A1 during time slots defined in advance.

Simulation techniques based on an activity schedule may conventionally make use of Large Language Model (LLM) artificial intelligence algorithms to generate behaviors and activities.

The activities imposed by the schedule are preferably the user's “lifestyle activities” that are not need-based activities, such as working, shopping, sports activity, etc. For example, an autonomous agent may be configured to work Monday to Friday from 8 a.m. to 7 p.m. and is therefore considered “absent” during these time slots.

In addition, the needs activities may be independent and may interrupt the lifestyle activities in the activity schedule; for example, the autonomous agent may interrupt its workday to go and eat.

The autonomous agent A1 (or autonomous agents) defined according to the parameters described above is then integrated into the 3D simulation instantiated from the digital twin J, during a step S4 of FIG. 2.

In this step S4, initialization parameters may be defined that will be used for an activity simulation step S5, for example such as the target duration of the activity simulation (e.g. in days, weeks or months), the time of year (in order to take into account holiday periods, define an average temperature, a sunrise time, etc.), a time increment/resolution of the simulation, etc.

In step S5, the activity Act.A1 of the autonomous agent A1 is simulated in the digital twin J instantiated in 3D in step S2. This activity simulation consists of letting the autonomous agent perform actions in the 3D simulation of the digital twin J, as it follows its activity schedule and its needs defined in step S3.

For example, the activity simulation may be integrated into the 3D engine (Unity3D, Unreal Engine, etc.) used to instantiate the digital twin in 3D. It may be implemented by several modes of interaction with the device replicas and with the simulated environment. This may include, for example, a forward kinematics mode (with animation data banks for lying down, sitting down, etc.), an inverse kinematics mode (animating the autonomous agent according to the interaction and adapted to a particular object), and/or a movement planning mode (“path planning”, where the autonomous agent moves by taking an optimal path and avoiding obstacles), etc.

According to one embodiment, part of its activity may be “free”, governed by its needs, and another part of its activity is “imposed” by its activity schedule. In such a configuration, the autonomous agent A1 does not behave in the same way from one simulation to another, even for a same digital twin J.

All activity of the autonomous agent may also be imposed prior to the simulation, for example based on the activity schedule. Alternatively, it is possible to develop a list of activities over given time slots, from which the autonomous agent A1 selects its actions randomly or in a chosen order.

Furthermore, in order to most effectively simulate potentially dangerous actual situations and unusual behaviors of the agent, it is possible to impose one or more actions/inactions on the autonomous agent A1 and/or on the 3D simulation of the digital twin J, which could jeopardize safety. For example, the autonomous agent A1 could be required to not eat for several days, or an uncontrolled dangerous situation could be simulated such as a flood or a fire in the 3D simulation of the digital twin J.

The simulation of the activity Act.A1 of the autonomous agent A1 is advantageously iterated over the equivalent of several weeks in an accelerated manner, preferably in a few real hours depending on the available computing resources.

According to one embodiment, the simulation is then accelerated by a factor of preferably 10 to 20 relative to real time and it is possible to execute time jumps (for example when autonomous agent A1 is sleeping or absent); thus, preferably, a real day of computing is equivalent to a 3-week activity simulation. To further accelerate the simulation, it is also possible to provide several parallel processing cores.

FIG. 5 illustrates an example simulation of the activity Act.A1 of the autonomous agent A1 interacting with the television replica Req1 and with the various device replicas Rl1, Rl2, Rp1, Rp2, Rmv and their sensors RC1 to RC6, in the room replica RPc1 of the digital twin J reproducing the environment of FIG. 1.

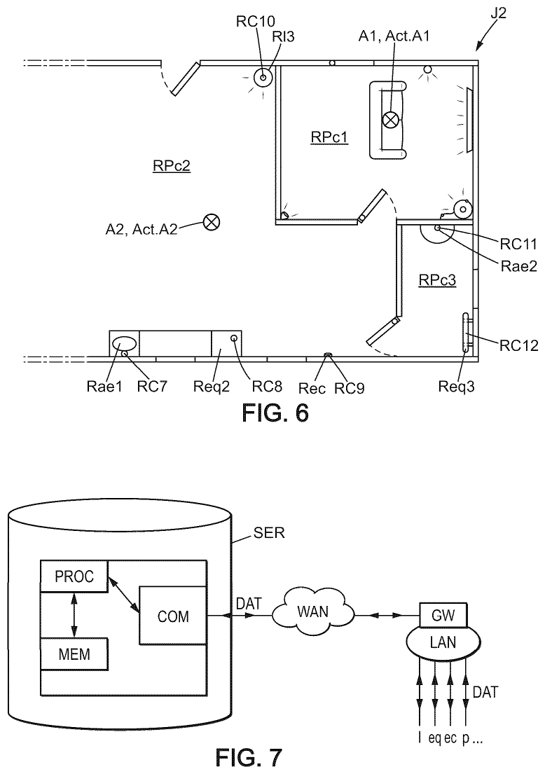

FIG. 6 illustrates another example simulation of the activities Act.A1 and Act.A2 of two autonomous agents A1, A2 interacting in another 3D simulation based on another digital twin J2, reproducing another real environment (not shown), with the room RPc1 and two additional rooms RPc2 and RPc3, and a plurality of devices, with faucet/water inlet replicas Rae1, Rae2, a refrigerator replica Req2, a radiator replica Req3, a light replica Rl3, a power supply replica Rec, etc., and their sensors RC7 to RC12.

In a step S6, annotated synthetic data is generated, comprising the measurements captured by the sensor replicas in the digital twin J during the activity simulation of step S5, as well as the data relating to the simulation of the activity itself, i.e. without necessarily having activated the sensors.

This data, captured and activity, is automatically labeled during the simulation (labels on the type of activity, the room where the agent is located, the duration of the activity, etc.) and constitutes synthetic training data, which will then be used to train the AI algorithm to be integrated into the real environment.

In a non-exhaustive manner, this training data may thus comprise:
the activity simulation data of the autonomous agent A1, as well as the labels and information relating to the type of activity, the time or duration of the activity, its number of occurrences during a day or a defined period,
the measurements captured by the sensor replicas, for example: if the autonomous agent A1 moved within the room to get a drink, it could have activated a faucet replica as well as a connected sensor that detects turning on the tap and the motion sensor replica Rmv for when the agent moves, and/or
the captured measurements of the state of the 3D simulation of the digital twin J, the ambient temperature of a room, the brightness, etc.

Optionally and in addition to the training data generated during step S5, annotated data brought in from another simulation (in particular with a similar digital twin and one or more similar autonomous agents), or real data from the real environment brought in by an operator/user, may be used for training the AI algorithm. Also optionally, all of the training data may be processed during step S6 to be converted into a desired format adapted to the targeted AI algorithm, in an automated manner and/or by a user.

In step S7, the AI algorithm is trained, preferably in a supervised manner, using this training data.

The AI algorithm is, for example, a classification algorithm (e.g. Multilayer Perceptron, Support Vector Machine), and its training may be, for example, a statistical optimization with cross-validation (e.g. gradient descent).

During the training of the AI algorithm, the AI produces an inference, where the behavior of the autonomous agent A1 is analyzed and identified for each activity or action undertaken by the autonomous agent. For example, the AI algorithm may identify whether the activity corresponds to “eating,” “sleeping,” “watching content on a television,” etc.

This inference may then be used for various applications, depending on the context. In the case of user safety and monitoring assistance, the inference may be used to identify whether the behavior of the autonomous agent A1 is unusual and/or dangerous, for example in comparison to the “average” behavior of the autonomous agent.

The inference by the AI algorithm may also be used to measure the availability of the autonomous agent (whether it can be “disturbed” by a ringtone, for example), or to predict preferred/future activities (for example, to optimize internet speed based on the hours of use of an internet router), detect a presence in a particular room (for example, in order to activate certain devices such as a lamp or a radiator), or others.

Optionally, the efficiency of the AI algorithm trained in this manner may then be evaluated during a step S7′. In this step, the trained AI algorithm is reintegrated into the activity simulation of the autonomous agent A1 in the 3D-instantiated digital twin J of step S5.

The goal here is to verify that the inferences produced by the trained AI algorithm properly correspond to the “real” simulation of the activity Act.A1 of the autonomous agent A1 and to the activation of the sensor replicas RC.

This step may additionally or alternatively comprise the comparison between a prediction by the AI algorithm of the future activity and the simulated “real” future activity of the autonomous agent A1, and/or the comparison between an availability measurement calculated by the AI algorithm and the simulated “real” availability of the autonomous agent A1.

The efficiency of the AI algorithm may for example be evaluated by a predefined threshold, or a precision measurement corresponding to the ratio between the number of inferences produced by the AI algorithm that are correct and the total number of inferences produced.

In the case where the comparison is not satisfactory (in this example, if the precision measurement is too low, for example below a threshold of 80%), meaning the inference produced by the AI algorithm does not correspond to the simulation of activity of the autonomous agent A1 at the end of step S7′, the training data from step S6 may be corrected.

In detail, the method may then be implemented once again, starting with step S3, where the autonomous agent A1 is parameterized differently, according to a different user profile, activity schedule, and/or needs model, and/or new autonomous agents are added to the simulation to generate new training data. Steps S7 and S7′ are then implemented once again based on these new activity simulations, until the comparison during the efficiency test S7′ is satisfactory (the accuracy measurement is above the threshold).

Similarly, in the case where the comparison is satisfactory at the end of step S7′, the method may be implemented once again starting with step S3, where the autonomous agent A1 is parameterized differently, and/or new autonomous agents are added to the simulation to generate new training data, the aim being to converge towards the best possible training for the AI algorithm. It may also optionally be provided to modify or adapt the digital twin J of step S2, for example if a new device is installed in the real environment E.

To improve the evaluation of the relevance of the responses produced by the AI algorithm, the simulation may (or may not) implement one or more dangerous situations, such as a fire and/or an unusual behavior of the autonomous agent A1 during step S7′.

A step S8 of FIG. 2 is then implemented, where the trained AI algorithm is integrated into the real environment E with the physical user(s) UT whose activity is to be monitored.

The AI algorithm may thus, for example, be integrated into a device in the real environment, such as an internet router, and/or into a device in a wide area network (in the “cloud”).

The trained AI algorithm is thus configured to be able to analyze all the activities of the physical user(s) UT during a subsequent step S9. In this step, for each measurement recorded by the sensors of the devices in the real environment E, whether direct activity of the user UT (turning on hotplates) or indirect activity/data (high temperature in a room for example), the AI algorithm infers and identifies the behavior.

According to a preferred embodiment, the activity analysis is done in real time and continuously. Alternatively, it may be planned to configure the activity analysis during predefined periods.

The activity analysis may then comprise a final step S10, where the AI algorithm is configured to continue its activity analysis (no action) or to generate an alert based on its inference and in the following cases, for example:
No action: the behavior of the user UT is identified as customary, the situation is classified as safe, and the state of the real environment E is identified as normal;
Alert: the behavior of the user UT is identified as unusual, the situation is classified as dangerous, and/or the state of the environment E is abnormal.

According to one embodiment, the type of alert generated is configured by the user prior to the inference by the AI algorithm in step S9. The type of alert may thus depend on the type of behavior and/or the type of dangerous situation and/or the user profile, and may include, for example:
contacting emergency services (firefighters, ambulance, police),
contacting a predefined person (a relative, a neighbor),
sending an alert report to the user, with or without required action, via a user device such as a mobile phone, and/or
performing one or more actions in the real environment E, such as triggering an alarm or cutting off the power to a device.

The user may also choose to set a target duration before contacting a person or emergency services, may choose not to issue an alert in certain cases of his or her choosing, etc.

The responses produced by the AI algorithm may alternatively be received by an external service, for example a provider in the real environment (internet provider, electricity provider, etc.), and the activity analysis and/or the generation of the alert and/or action in the real environment may be managed by this service rather than by the AI algorithm.

Regardless of what is inferred in step S10, it may also be provided to send an activity report to one or more users (television activation time, bedtime, etc.) and/or the state of the environment (temperature, humidity, electricity consumption, etc.) on a daily basis for example, and/or to send a proposal to the user about managing the activation or deactivation of a sensor, via a user terminal.

According to another embodiment, the AI algorithm implemented in the real environment E in step S8 may be updated regularly, with new training data that is real and/or simulated according to steps S3 to S7/S7′ described above. This update may take place spontaneously, regularly, and/or at user request.

Furthermore, the user may have an interface, for example implemented on the user terminal or on a device provided for this purpose, such as a monitoring device or home automation device, for configuring and controlling the AI algorithm as well as the parameters relating to the creation of the autonomous agents (or of the digital twin J), as described above.

The method described above for monitoring human activity may further be instantiated:
remotely, on a remote machine such as the server SER (in the “cloud”), communicating via the wide area network WAN and receiving the data DAT from the sensors C1 . . . C6 of the real environment from the local area network LAN and via the gateway GW;
locally, on one of the devices of the local area network LAN of the real environment E, such as a computer or a user terminal connected to the LAN network for example.

Thus, in either of the “remote” or “local” embodiments, the alert/report generated by the AI algorithm in response to the analyzed human activity, and/or the activation/deactivation of devices in the real environment E, may thus be carried out locally (on a unit connected to the local area network) or remotely (on a unit connected to the server SER for example).

FIG. 7 illustrates, by way of example, a processing circuit for implementing the method described in this disclosure, which may comprise:
the gateway GW, configured to receive the data DAT captured by the various device sensors (e.g. the television eq, the light fixture l, the power supply ec, the window blind p, etc.) interconnected on the local area network LAN of the real environment E, and to transmit the data to the wide area network WAN;
the wide area network WAN, configured to receive and transmit the data DAT to the remote server SER;
the remote server SER, comprising a communication interface COM connected to the wide area network WAN, a processor PROC capable of controlling the communication interface COM of the server, and a memory MEM which at least stores instructions of a computer program and/or of the AI algorithm. The memory MEM is accessible by the processor PROC in order to implement the above method when the processor PROC of the processing circuit executes the program instructions. The interface COM also receives instructions from the processor PROC, which it then transfers via the WAN network to the LAN network; the instructions may be the alert and/or the activation/deactivation of devices, based on the inference by the AI algorithm. Although the present disclosure has been described with reference to one or more examples, workers skilled in the art will recognize that changes may be made in form and detail without departing from the scope of the disclosure and/or the appended claims.

What is claimed is:

1. A method for determining a human activity in an environment comprising at least one usage sensor for at least one device of the environment, the method being implemented by at least one processing circuit comprising an artificial intelligence and comprising:
learning by the artificial intelligence and an inference by the artificial intelligence in order to determine the human activity in said environment; and
for the learning by the artificial intelligence:
generating artificial intelligence training data, based on a simulation of an activity of at least one autonomous agent operating within a simulation of the environment generated from a digital twin of the real environment and using at least one digital replica of said device.

2. The method according to claim 1, wherein the inference by the artificial intelligence is carried out based on data captured during the use of said at least one device by at least one physical user, while having knowledge of the training data acquired from simulated uses of the digital replica of the device by said at least one autonomous agent.

3. The method according to claim 2, wherein the at least one autonomous agent used for generating the training data is selected based on a profile of the at least one physical user.

4. The method according to claim 1, comprising initializing the digital twin of the real environment prior to generating training data for the artificial intelligence,
said digital twin being configured to reproduce a state and a behavior of the real environment by simulating the environment of said real environment, comprising the digital replica of said at least one device in the real environment.

5. The method according to claim 4, wherein the digital twin is generated from data of the real environment, including at least:
a type of business premises or residential premises,
a surface area of said premises,
functional spaces in said surface area, and types of functions of said spaces,
a state of said premises.

6. The method according to claim 1, wherein said at least one device in the real environment comprises at least:
a sensor for detecting an opening and/or closing of a water inlet;
a sensor for a connected power outlet;
a presence sensor;
a pressure sensor;
a sensor for detecting the turning on and/or off of a light;
a motion sensor for a door, blind, shutter, and/or window;
a thermostatic sensor;
a usage sensor for a household appliance; and/or
a usage sensor for a connected terminal.

7. The method according to claim 1, wherein said at least one sensor is connected to a local area network linked to a gateway connected to a server via a wide area network.

8. The method according to claim 1, further comprising monitoring an efficiency of the artificial intelligence,
wherein the inference by the artificial intelligence is implemented on the basis of data captured during the simulation of the activity of the at least one autonomous agent operating within the simulation of the environment generated from the digital twin of the real environment, while having knowledge of the training data acquired from simulated uses of the digital replica of the device by the at least one autonomous agent,
wherein a comparison of the inference produced by the artificial intelligence and the simulation of the activity of the at least one autonomous agent is evaluated, and if the comparison is greater than a predefined threshold, said training data is corrected relative to said data captured during the simulation of the activity of the at least one autonomous agent.

9. The method according to claim 8, comprising generating at least one new autonomous agent, depending on said comparison exceeding the predefined threshold, in order to generate new training data for the artificial intelligence.

10. The method according to claim 1, comprising an increase in a speed of operating of the at least one autonomous agent within said simulation of the environment generated from the digital twin, compared to an actual operating of at least one physical user within the real environment, in order to accelerate the simulation of activity by the at least one autonomous agent and of the generation of training data.

11. The method according to claim 1, wherein each autonomous agent operates in said simulation of the environment according to a decision made by said autonomous agent based on a model of needs of said autonomous agent.

12. A non-transitory computer readable medium comprising a computer program stored thereon comprising instructions for implementing a method for determining a human activity in an environment comprising at least one usage sensor for at least one device of the environment, when the instructions are executed by a processing circuit, the method comprising:
learning by an artificial intelligence and an inference by the artificial intelligence in order to determine the human activity in said environment; and
for the learning by the artificial intelligence:
generating artificial intelligence training data, based on a simulation of an activity of at least one autonomous agent operating within a simulation of the environment generated from a digital twin of the real environment and using at least one digital replica of said device.

13. A device comprising:
a processing circuit comprising an artificial intelligent configured to determine a human activity in an environment comprising at least one usage sensor for at least one device of the environment by:
learning by the artificial intelligence and an inference by the artificial intelligence in order to determine the human activity in said environment; and
for the learning by the artificial intelligence:
generating artificial intelligence training data, based on a simulation of an activity of at least one autonomous agent operating within a simulation of the environment generated from a digital twin of the real environment and using at least one digital replica of said device.
